(19) United States
(12) Patent Application Publication
(10) Pub. No.: US 2014/0225232 A1
(43) Pub. Date: Aug. 14, 2014

(54) REDUCING CONTAMINATION DURING ATOMIC LAYER DEPOSITION

(71) Applicant: TAIWAN SEMICONDUCTOR MANUFACTURING COMPANY LIMITED, Hsin-Chu (TW)

(72) Inventors: Su-Horng Lin, Hsinchu City (TW); Kuang-Kuo Koai, JhongLi (TW)

(73) Assignee: Taiwan Semiconductor Manufacturing Company Limited, Hsin-Chu (TW)

(21) Appl. No.: 13/762,543

(22) Filed: Feb. 8, 2013

(51) Int. Cl. H01L 21/02; H01L 21/3205

(52) U.S. Cl. CPC H01L 21/0228; H01L 21/3205
USPC 257/632; 118/733; 118/663; 438/763; 438/680; 257/734

(57) ABSTRACT

Atomic layer deposition (ALD) techniques typically involve briefly exposing the surface of a substrate to a precursor within an atomic layer deposition chamber, and purging the chamber with a purge gas, such as nitrogen, before exposing the substrate to a second precursor. A series of such cycles results in the deposition of microscopically thin film layers on the substrate surface that are further processed to generate a semiconductor component. In order to reduce unintended oxygen deposition, the chamber is typically evacuated to a vacuum level of 10e⁻⁰⁶ torr-liters/second, which is suitable for the related techniques of chemical vapor deposition. However, atomic layer deposition is demonstrably more sensitive to oxygen contamination, due to the exposure of each layer to residual oxygen within the chamber. Tighter process control is achievable by performing atomic layer deposition at a higher vacuum level, not exceeding approximately 10e⁻⁰⁶ torr-liters/second, in order to reduce oxygen contamination.

### BACKGROUND

The present disclosure is related to atomic layer deposition techniques, wherein a substrate is positioned within an atomic layer deposition chamber and exposed to a series of precursors to form microscopically thin layers of deposited material.

### SUMMARY

This Summary is provided to introduce a selection of concepts in a simplified form that are further described below in the detailed description. This summary is not intended to be an extensive overview of the claimed subject matter, identify key factors or essential features of the claimed subject matter, nor is it intended to be used to limit the scope of the claimed subject matter.

Atomic layer deposition is typically performed under a vacuum in order to reduce contamination of formed layers by deposited oxygen. The vacuum within the atomic layer deposition chamber is typically held at a vacuum level of 10e⁻⁰⁶ torr-liters/second, which is a conventionally accepted vacuum level for the related field of chemical vapor deposition.

However, atomic layer deposition can be demonstrably more sensitive to oxygen contamination than chemical vapor deposition, due to the deposition of a series of layers, each of which is exposed to oxygen. Due to this sensitivity, the performance of atomic layer deposition at an increased vacuum level not exceeding approximately 10e⁻⁰⁸ torr-liters/second, thus providing a higher level of vacuum that enables a significant reduction of oxygen contamination, resulting in tighter process control. Additional reduction of oxygen and reduction of oxygen contamination is achievably by applying still higher vacuum levels, such as 10e⁻¹⁰ torr-liters/second.

The following description and annexed drawings set forth certain illustrative aspects and implementations. These are indicative of but a few of the various ways of embodying one or more aspects of the presented techniques. Other aspects, advantages, and novel features of the disclosure will become apparent from the following detailed description when considered in conjunction with the annexed drawings.

### DESCRIPTION OF THE DRAWINGS

Aspects of the disclosure are understood from the following detailed description when read with the accompanying drawings. It will be appreciated that elements and/or structures of the drawings are not necessarily be drawn to scale. Accordingly, the dimensions of the various features is arbitrarily increased and/or reduced for clarity of discussion.

FIG. 1 is an illustration of an exemplary atomic layer deposition technique.

FIG. 2 is a table illustrating the sensitivity of atomic layer deposition to oxygen contamination at various vacuum levels.

FIG. 3 is an illustration of an exemplary atomic layer deposition technique in accordance with some embodiments.

FIG. 4 is a flow chart illustrating an exemplary method of depositing a layer on a surface of a substrate through an atomic layer deposition technique in accordance with some embodiments.

FIG. 5 is an illustration of an exemplary computer-readable storage device comprising instructions configured to cause a computing device to perform the techniques presented herein.

FIG. 6 is an illustration of an exemplary atomic layer deposition controller operating the components of an atomic layer deposition device to achieve a deposition of a precursor on a substrate in accordance with the techniques presented herein.

### DETAILED DESCRIPTION

Embodiments or examples, illustrated in the drawings, are disclosed below using specific language. It will nevertheless be understood that the embodiments or examples are not intended to be limiting. Any alterations and modifications in the disclosed embodiments, and any further applications of the principles disclosed in this document are contemplated as would normally occur to one of ordinary skill in the pertinent art.

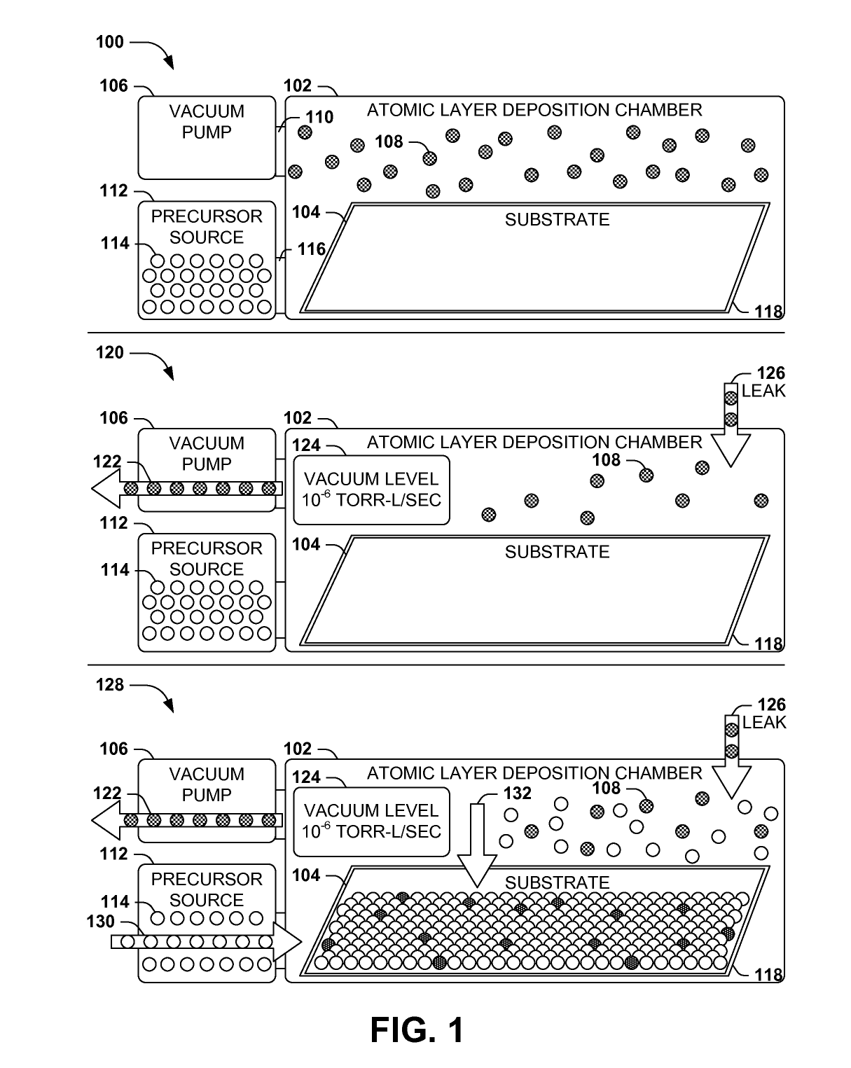

FIG. 1 presents an illustration of an exemplary atomic layer deposition (ALD) technique for forming a layer on a substrate, such as the exposure of a silicon wafer to a disilane (Si₂H₆) precursor gas to form a thin film of silicon dioxide. In this exemplary scenario, at a first time point 100, an atomic layer deposition chamber 102 comprises a substrate 104, which is positioned on a substrate stage. The atomic layer deposition chamber 102 contains molecules of oxygen 108 and other gases, such as nitrogen. The atomic layer deposition chamber 102 is in controllable communication with a vacuum pump 106, which is capable of extracting oxygen 108 and other gases by extraction through a vacuum outlet 110. The atomic layer deposition chamber 102 is also in controllable communication with a precursor source 112, which stores molecules of a precursor 114 and is capable of injecting the precursor 114 into the atomic layer deposition chamber 102 through a precursor inlet 116. In order to perform the atomic layer deposition, at a second time point 120, the atomic layer deposition chamber 102 activates the vacuum pump 106 to evacuate 122 the atomic layer deposition chamber 102 through the vacuum outlet 110 to a vacuum level 124 of 1.0e⁻⁰⁶ torr-liters/second. The vacuum pump 106 maintains the vacuum level 124 in order to offset the effects of leaks 126 of oxygen 108 and other gases into the atomic layer deposition chamber 102 caused by punctures, gaps, etc. in seals, valves, hoses, etc. associated with the atomic layer deposition chamber 102. At a third time point 128, while the vacuum pump 106 maintains the vacuum level 124, the precursor source 112 injects 130 the precursor 114 through the precursor inlet 116 and into the atomic layer deposition chamber 102, resulting in a depositing 132 of the precursor 114 onto the surface of the substrate 104. This exposure is performed for a relatively short duration, such as one second, after which the atomic layer deposition chamber 102 is purged by injecting a purge gas, such as nitrogen, before a second instance of the steps illustrated at the second time point 120 and the third time point 128 to expose the substrate 104 to another precursor in furtherance of a chemical reaction on the surface of the substrate 104, or to form a second deposition layer. Application of this sequence a number of times results in the formation of a stack of layers on the surface of the substrate 104, which are further processed to form various semiconductor components.

As illustrated in the exemplary scenario of FIG. 1, atomic layer deposition techniques are often performed under vacuum levels approximating 1.0e⁻⁰⁶ torr-liters/second to reduce oxygen contamination of the deposited layers. This pressure level is considered satisfactory for the related field of chemical vapor deposition, where the chamber is filled with a gas or vapor that chemically reacts with the surface of the substrate to form one or more layers that are further processed to form one or more semiconductor components. By contrast, atomic layer deposition involves the exposure of the surface of each individually formed layer to the oxygen contaminants, potentially exacerbating oxygen contamination. Thus, atomic layer deposition techniques are demonstrably more sensitive to oxygen contamination than chemical vapor deposition techniques.

In view of this observation, alternative atomic layer deposition techniques are disclosed that are capable of performing deposition within an atomic layer deposition chamber 102 that has been evacuated to a higher vacuum level 124, such as approximately 1.0e⁻⁰⁸ torr-liters/second. Increasing the vacuum level 124 during atomic layer deposition reduces the exposure of the individually formed layers to oxygen 108, resulting in tighter process control and higher reliability of resulting components. Further increasing the vacuum level, such as at 1.0e⁻¹⁰ torr-liters/second, enables further evacuation of oxygen and further reduction of oxygen contamination.

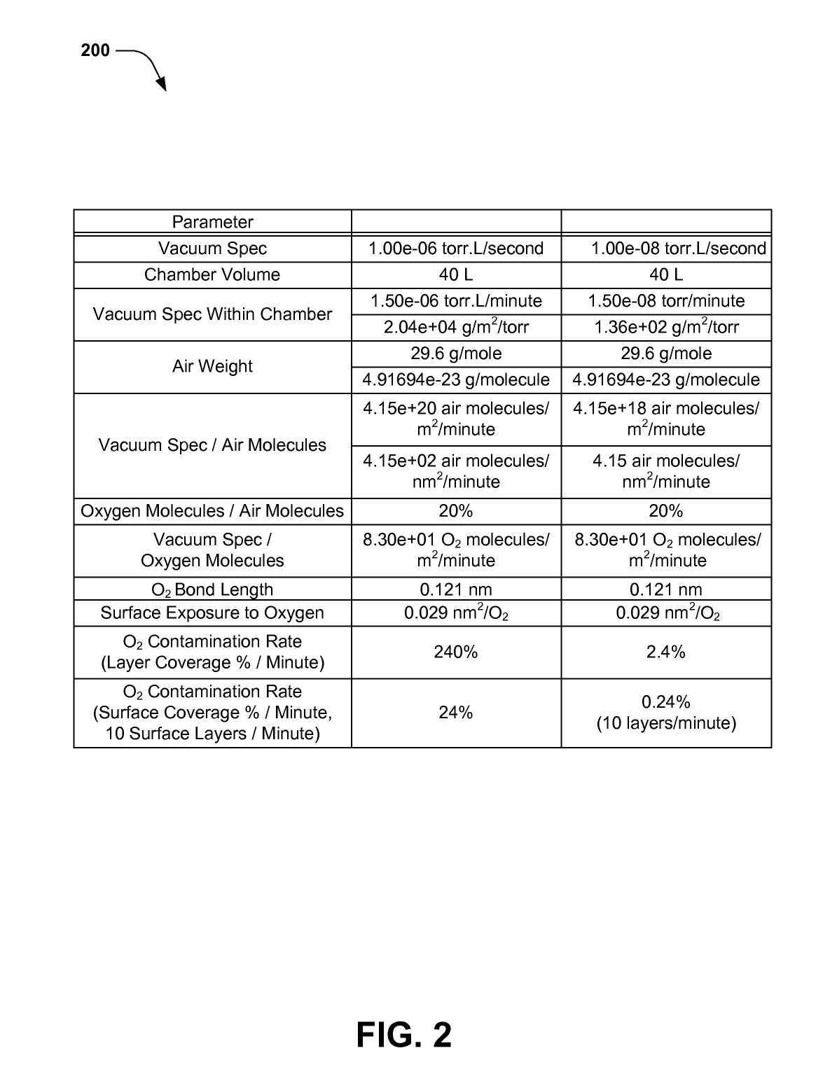

FIG. 2 presents a table 200 indicating a series of observations and calculations demonstrating the sensitivity of atomic layer deposition when performed at 1.00e⁻⁰⁶ torr-liters/second and 1.00e⁻⁰⁸ torr-liters/second, as narrated according to the downward vertical sequence of data within the table 200. A vacuum level 124 of 1.00e⁻⁰⁶ torr-liters/second for a 40-liter atomic layer deposition chamber 102 results in an applied vacuum of 2.04e⁺⁰⁴ gm²/torr, but a vacuum level 124 of 1.00e⁻⁰⁸ torr-liters/second results in an applied vacuum of 1.36e⁺⁰² g/m²/torr for the 40-liter atomic layer deposition chamber 102. Next, taking into account the typical weight of air (29.6 g/mole), an applied vacuum of 1.00e⁻⁰⁶ torr-liters/second results in an applied pressure of 4.15e⁺²⁰ air molecules/m²/minute, or 4.15e⁺⁰² air molecules/nm²/minute; while the applied vacuum of 1.00e⁻⁰⁸ torr-liters/second results in an applied pressure of 4.15e⁺¹⁸ air molecules/m²/minute, or 4.15e⁺⁰⁰ air molecules/nm²/minute. Next, considering the typical concentration of 20% of air molecules comprising oxygen 108 and the O₂ bond length of 0.121 nm, an applied vacuum of 1.00e⁻⁰⁶ torr-liters/second results in an O₂ contamination rate of 240%, or 24% per layer at a rate of 10 layers/second. However, an applied vacuum of 1.00e⁻⁰⁸ torr-liters/second results in only a 2.4% O₂ contamination rate, or a 0.24% contamination rate per layer at a rate of 10 layers/second. These observations thus demonstrate the advantage of performing atomic layer deposition under a higher vacuum level 124 not exceeding approximately 1.00e⁻⁰⁸ torr-liters/second.

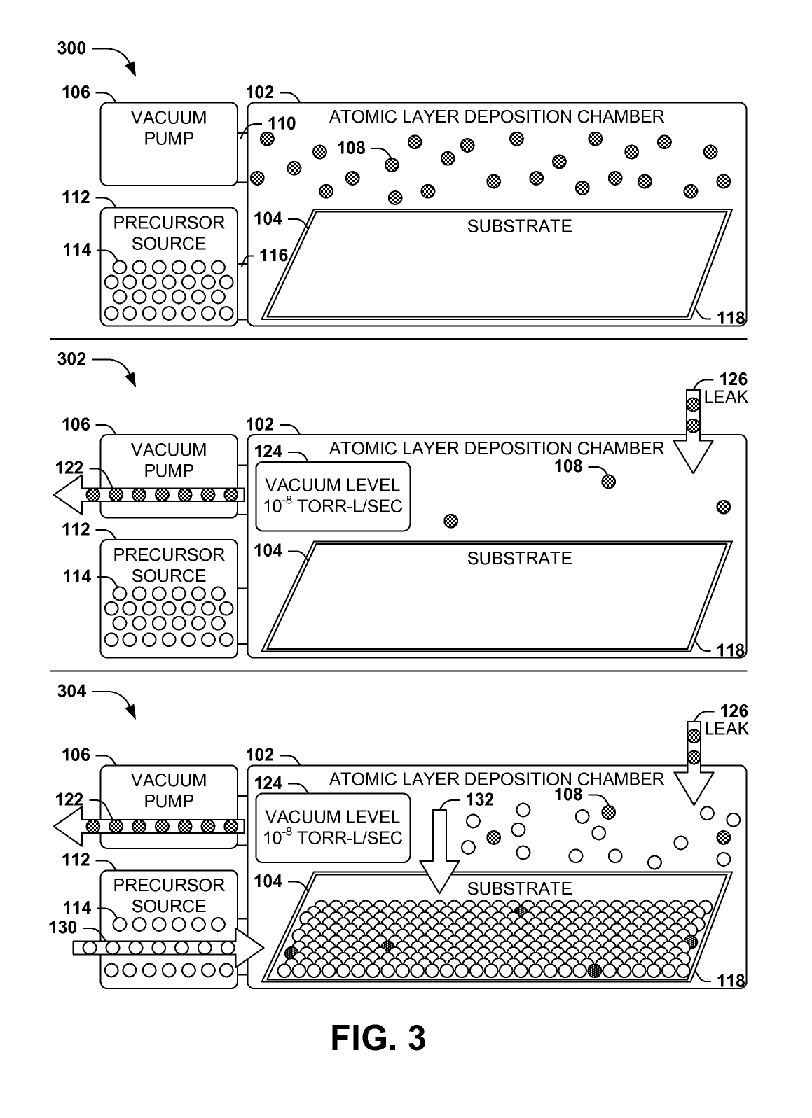

FIG. 3 presents an illustration of an exemplary scenario depicting atomic layer deposition performed in accordance with some embodiments presented herein. In this exemplary scenario, at a first time point 300, the substrate 104 is positioned on the substrate stage 118 within the atomic layer deposition chamber 102 in the presence of oxygen 108 and other molecules. At a second time point 302, the vacuum pump 106 is operated to evacuate 122 oxygen 108 and other molecules from the atomic layer deposition chamber 102 through the vacuum outlet 110 to a desired vacuum level 124 of approximately 10e⁻⁰⁸ torr-liters/second, and this vacuum level 124 is maintained to counteract leaks 126 potentially occurring through seals, valves, hoses, between the housing of the atomic layer deposition chamber 102 and a second component, etc. At a third time point 304, the precursor source 112 is operated to inject 130 the precursor 114 through the precursor inlet 116 and into the atomic layer deposition chamber 102, resulting in a depositing 132 of the precursor 114 on the surface of the substrate 104. By performing the depositing 132 in the presence of significantly less oxygen 108 due to the higher vacuum level 124 not exceeding approximately 10e⁻⁰⁸ torr-liters/second, the atomic layer deposition illustrated in FIG. 3 achieves the formation of a layer on the surface of the substrate 104 through atomic layer deposition with significantly lower oxygen contamination and tighter process control in accordance with the techniques presented herein.

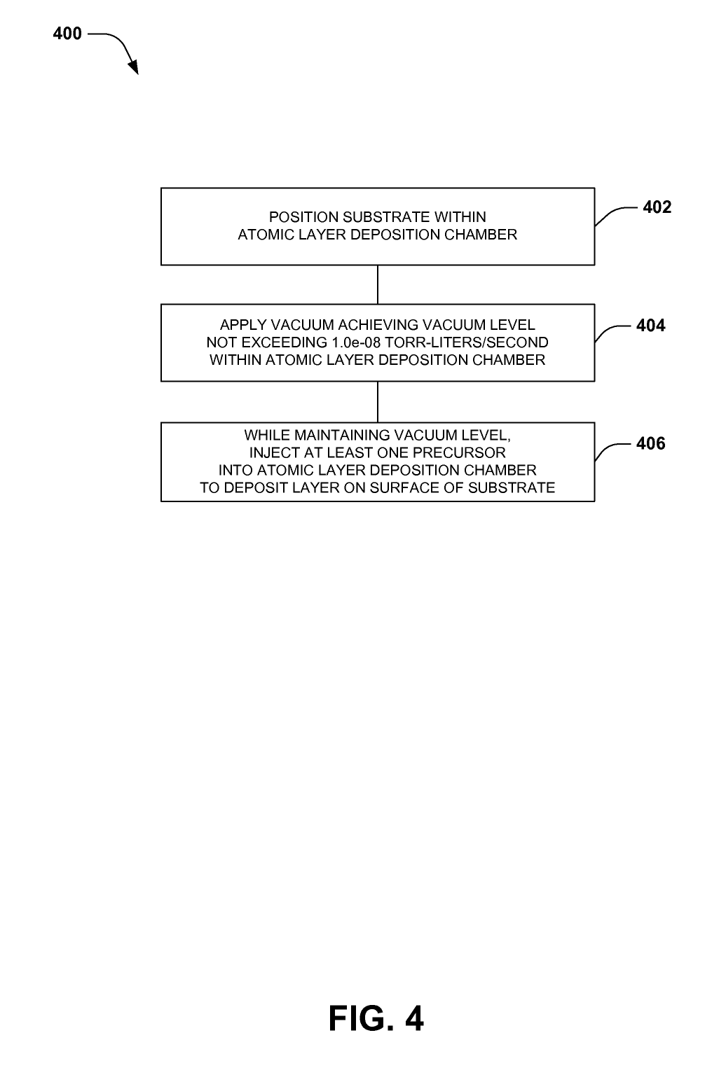

FIG. 4 presents an illustration of an exemplary method 400 of depositing a layer on a surface of a substrate 104 in accordance with the techniques presented herein. The exemplary method 400 involves positioning 402 the substrate within an atomic layer deposition chamber 102. The exemplary method 400 also involves applying 404 a vacuum achieving a vacuum level 124 not exceeding approximately 1.0e⁻⁰⁸ torr-liters/second within the atomic layer deposition chamber 102. The exemplary method 400 also involves, while maintaining the vacuum level 124, injecting 406 at least one precursor into the atomic layer deposition chamber to deposit the layer on the surface of the substrate. By enabling the exposure of the surface of the substrate 104 to the precursor 114 at the higher vacuum level 124 to reduce contamination by oxygen 108 and other gases, the exemplary method 400 achieves the deposition of a significantly less contaminated layer on the surface of the substrate 104 as compared to other techniques.

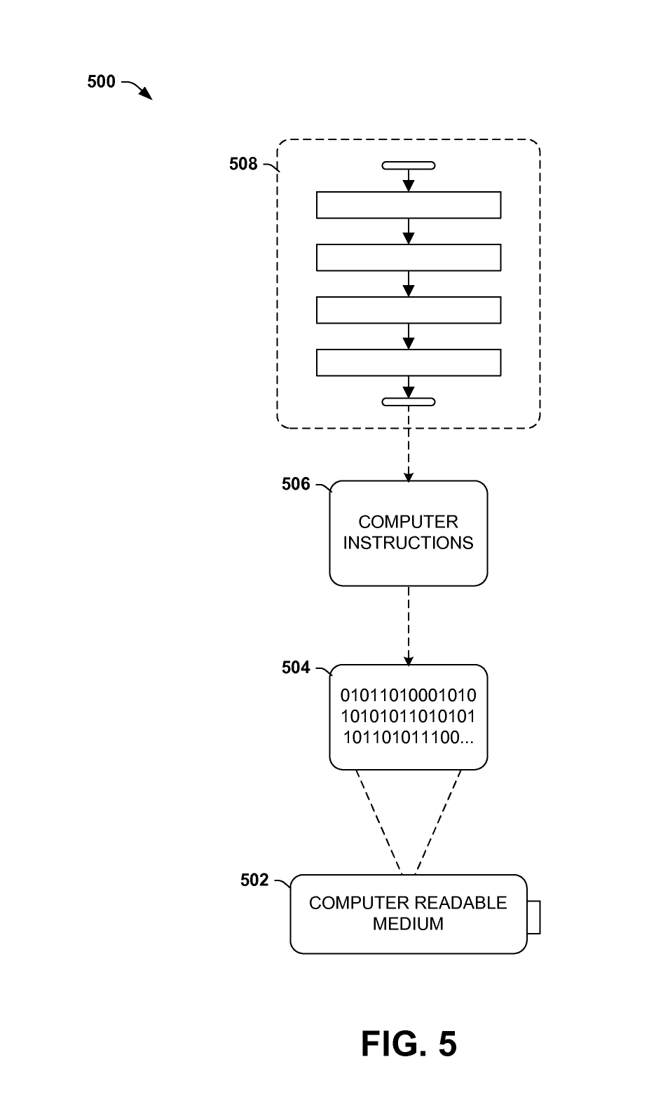

Still another embodiment involves a computer-readable medium comprising processor-executable instructions configured to implement one or more of the techniques presented herein. An example embodiment of a computer-readable medium or a computer-readable device that is devised in these ways is illustrated in FIG. 5, wherein an implementation 500 comprises a computer-readable medium 502, such as a CD-R, DVD-R, flash drive, a platter of a hard disk drive, etc., on which is encoded computer-readable data 504. This computer-readable data 506, such as binary data comprising a plurality of zeroes and ones, in turn comprises a set of computer instructions 506 configured to operate according to one or more of the principles set forth herein. In a first embodiment 500, the processor-executable computer instructions 506 are configured to perform a method, such as at least some of the exemplary method 400 of FIG. 4. In a second embodiment, the processor-executable computer instructions 504 are configured to implement a system such as at least some of that illustrated in FIG. 3. Many such computer-readable media are devised by those of ordinary skill in the art that are configured to operate in accordance with the techniques presented herein.

Some variations of respective aspects of the techniques presented herein enable additional advantages and/or reduce disadvantages as compared with other variations of the techniques presented herein and/or other techniques.

A first variable aspect involves the types of layers and devices formable according to the techniques presented herein. For example, high-k metal gate materials and source/drain region contact material are capable of being formed from layers formed on the surface of the substrate 104 according to the techniques presented herein, and thus provide tighter, more predictable behaviors or characteristics due to decreased oxygen contamination.

A second variable aspect involves the vacuum pump 106 provided to achieve and maintain the vacuum level 124. The vacuum pump is configured to achieve a vacuum level 124 not exceeding approximately 10e⁻⁰⁸ torr-liters/second within the atomic layer deposition chamber 102. Additionally, integrating a pressure detector with the atomic layer deposition chamber 102 that is configured to detect the vacuum level within the atomic layer deposition chamber enables a vacuum pump 106 to adjust the vacuum power to maintain the vacuum level 124 not exceeding approximately 10e⁻⁰⁸ torr-liters/second within the atomic layer deposition chamber 102.

A third variable aspect involves the seals applied to the valves, hoses, housing, etc. of the atomic layer deposition chamber 102. Selecting such seals to resist air leaks during the vacuum level 124 not exceeding approximately 1.0e⁻⁰⁸ torr-liters/second within the atomic layer deposition chamber facilitates the maintenance of the vacuum level 124.

A fourth variable aspect involves the further operation of the vacuum pump 106 during the atomic layer deposition. As a first example, atomic layer deposition often involves removing undeposited precursor from the atomic layer deposition chamber 102. The vacuum pump 106 enables a restoration of the vacuum level 124 not exceeding approximately 1.0e⁻⁰⁸ torr-liters/second within the atomic layer deposition chamber 102 after removing the undeposited precursor. To this end, some atomic layer deposition devices include a purge gas source storing a purge gas and controllably connected with the atomic layer deposition chamber 102 through a purge gas inlet. Purging the atomic layer deposition chamber 102 by injecting the purge gas, and then evacuating the atomic layer deposition chamber 102 by activating the vacuum pump 106 to restore the vacuum level 124 not exceeding approximately 1.0e⁻⁰⁸ torr-liters/second, prepares the atomic layer deposition chamber 102 for the injection of a second precursor 114 stored by a second precursor source in order to deposit another layer or to perform surface chemistry on the surface of the substrate 104.

As an exemplary embodiment of these techniques, an atomic layer deposition controller integrated with the atomic layer deposition device is configured to operate the vacuum pump 106 to achieve a vacuum level 124 not exceeding approximately 1.0e⁻⁰⁸ torr-liters/second within the atomic layer deposition chamber 102; while maintaining the vacuum level 124, operate the precursor source 112 to inject the precursor 114 into the atomic layer deposition chamber 102 to deposit a layer on the surface of the substrate 104; after depositing the layer on the surface of the substrate 104, operate the purge gas source to purge undeposited precursor from the atomic layer deposition chamber 102; and after purging the undeposited precursor, operate the vacuum pump 106 to maintain the vacuum level 124 not exceeding approximately 1.0e⁻⁰⁸ torr-liters/second within the atomic layer deposition chamber 102. Successive cycles of this process enable the formation of a stack of layers on the substrate 104 that are further processed to create one or more semiconductor components.

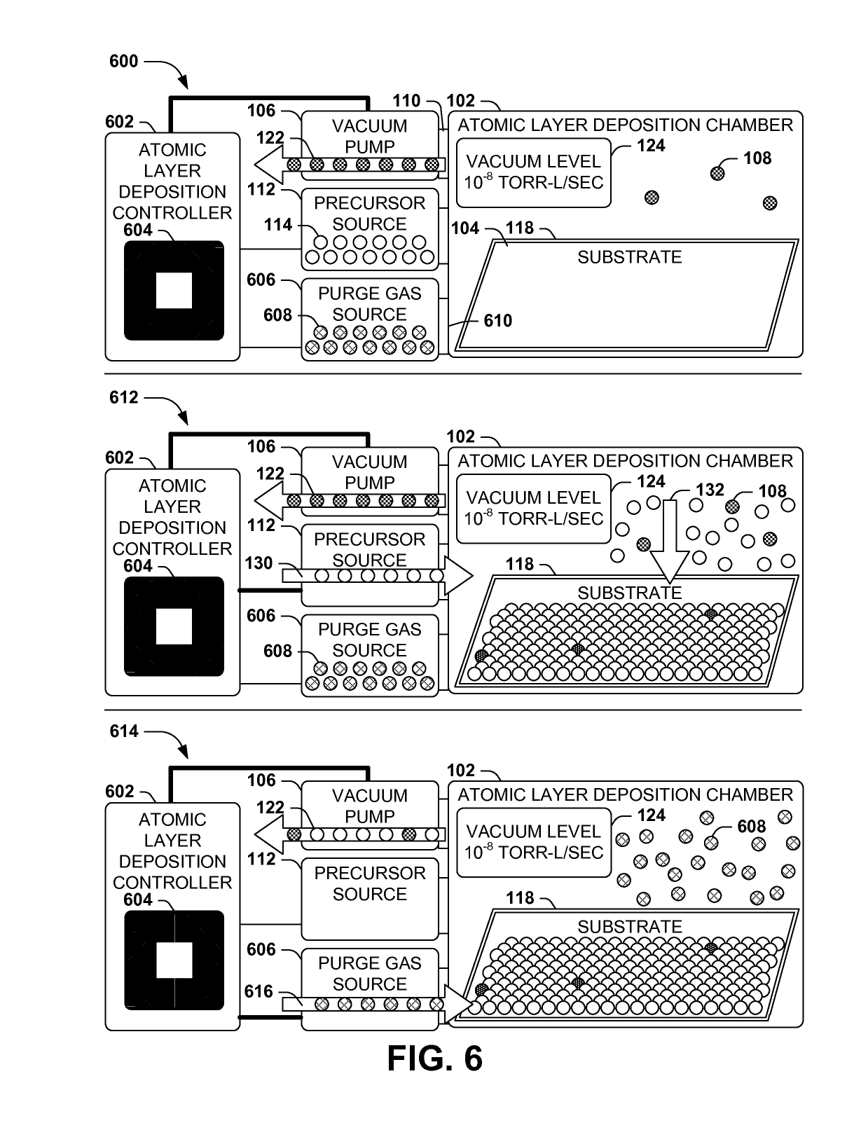

FIG. 6 presents an illustration of an exemplary atomic layer deposition device comprising an atomic layer deposition chamber 102 housing a substrate 104 positioned on a substrate stage 118, and an atomic layer deposition controller 602 operably coupled with a vacuum pump 106, a precursor source 112, and a purge gas source 606 storing a purge gas 608, such as nitrogen, and controllably communicating with the atomic layer deposition chamber 102 through a purge gas inlet 610. In this exemplary device, the atomic layer deposition controller 602 comprises a processor 604 executing instructions that cause the atomic layer deposition device to operate according to the techniques presented herein. At a first time point 600, the atomic layer deposition controller 602 activates the vacuum pump 106 to evacuate 122 oxygen 108 from the atomic layer deposition chamber 102 and to achieve a vacuum level 124 not exceeding approximately 1.0e⁻⁰⁸ torr-liters/second. At a second time point 612, the atomic layer deposition controller 602 activates the precursor source 112 to inject 130 the precursor 114 into the atomic layer deposition chamber 102 for a brief duration such as one second, thus achieving a depositing 132 of the precursor 114 onto the substrate 104, while continuing to activate the vacuum pump 106 to continue evacuating 122 oxygen 108 entering the atomic layer deposition chamber 102 due to leakage. At a third time point 614, following the depositing 132 of the precursor 114 onto the substrate 104, the atomic layer deposition controller 602 activates the purge gas source 606 to inject 616 the purge gas 608 into the atomic layer deposition chamber 102, while also continuing to activate the vacuum pump 106, thereby flushing the atomic layer deposition chamber 102 of molecules of unreacted precursor 608 and any gaseous or vaporous chemical byproducts, as well as any residual oxygen 108. Following the flushing, the atomic layer deposition controller 602 again activates evacuates 122 the atomic layer deposition chamber 102 to remove the purge gas 608, as well as any other gaseous or vaporous substances, and again performs the injection 130 of the same or a different precursor 114 as illustrated at the second time point 612. The atomic layer deposition controller 602 continues the cycle illustrated in the exemplary scenario of FIG. 6 to fabricate a stack of layers on the substrate 118 that are further processed to generate a set of semiconductor components.

In view of these observations, an embodiment of the techniques provided herein comprises an atomic layer deposition device that is capable of depositing a layer on a surface of a substrate. The atomic layer deposition device comprises an atomic layer deposition chamber. The atomic layer deposition device also comprises a precursor source storing a precursor and controllably connected with the atomic layer deposition chamber through a precursor inlet. The atomic layer deposition device also comprises a vacuum pump that is controllably connected with the atomic layer deposition chamber through a vacuum outlet, and configured to achieve a vacuum level not exceeding approximately 1.0e⁻⁰⁸ torr-liters/second within the atomic layer deposition chamber. An atomic layer deposition device configured in this manner is capable of depositing a layer on the surface of the substrate 104 in accordance with the techniques presented herein. Another embodiment of the techniques provided herein comprises a semiconductor device comprising at least one component formed from the layer deposited by the atomic layer deposition device provided herein.

A second embodiment of the techniques provided herein comprises a method of depositing a layer on a surface of a substrate in accordance with the techniques presented herein. The method involves positioning the substrate within an atomic layer deposition chamber. The exemplary method also involves applying a vacuum achieving a vacuum level not exceeding approximately 1.0e⁻⁰⁸ torr-liters/second within the atomic layer deposition chamber. The method also involves, while maintaining the vacuum level, injecting at least one precursor into the atomic layer deposition chamber to deposit the layer on the surface of the substrate. Still another embodiment of the techniques provided herein comprises a semiconductor device comprising at least one component formed from the layer deposited according to this method.

Although the subject matter has been described in language specific to structural features and/or methodological acts, it is to be understood that the subject matter of the appended claims is not necessarily limited to the specific features or acts described above. Rather, the specific features and acts described above are disclosed as example forms of implementing the claims.

Various operations of embodiments are provided herein. The order in which some or all of the operations are described should not be construed as to imply that these operations are necessarily order dependent. Alternative ordering will be appreciated by one skilled in the art having the benefit of this description. Further, it will be understood that not all operations are necessarily present in each embodiment provided herein.

It will be appreciated that layers, features, elements, etc. depicted herein are illustrated with particular dimensions relative to one another, such as structural dimensions and/or orientations, for example, for purposes of simplicity and ease of understanding and that actual dimensions of the same differ substantially from that illustrated herein, in some embodiments. Additionally, a variety of techniques exist for forming the layers, features, elements, etc. mentioned herein, such as implanting techniques, doping techniques, spin-on techniques, sputtering techniques such as magnetron or ion beam sputtering, growth techniques, such as thermal growth and/or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used in either the detailed description or the claims, such terms are intended to be inclusive in a manner similar to the term “comprising”.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims.

1.-9. (canceled)

10. A method of depositing a layer on a surface of a substrate, comprising:
positioning the substrate within an atomic layer deposition chamber;
applying a vacuum achieving a vacuum level not exceeding approximately 1.0e⁻⁰⁸ torr-liters/second within the atomic layer deposition chamber; and
while maintaining the vacuum level, injecting at least one precursor into the atomic layer deposition chamber to deposit the layer on the surface of the substrate.

11. The method of claim 10, the layer comprising a high-k metal dielectric material.

12. The method of claim 10, the layer comprising a source/drain region contact material.

13. The method of claim 10, further comprising, while injecting the at least one precursor into the atomic layer deposition chamber:
detecting the vacuum level within the atomic layer deposition chamber; and
adjusting a vacuum power of the vacuum to maintain the vacuum level not exceeding approximately 1.0e⁻⁰⁸ torr-liters/second within the atomic layer deposition chamber.

14. The method of claim 10, further comprising, after injecting the at least one precursor into the atomic layer deposition chamber:
removing undeposited precursor from the atomic layer deposition chamber.

15. The method of claim 14, removing the undeposited precursor from the atomic layer deposition chamber comprising:
purging the atomic layer deposition chamber with a purge gas.

16. The method of claim 14, further comprising, after removing the undeposited precursor from the atomic layer deposition chamber:
injecting at least one second precursor into the atomic layer deposition chamber to deposit a second layer over the layer.

17. The method of claim 10, comprising mitigating leaks within the atomic layer deposition chamber to maintain the vacuum level not exceeding approximately 1.0e⁻⁰⁸ torr-liters/second within the atomic layer deposition chamber.

18.-20. (canceled)

21. A method, comprising:
injecting at least one precursor into an atomic layer deposition chamber in which a substrate is located while maintaining a vacuum level that does not exceed approximately 1.0e⁻⁰⁸ torr-liters/second within the atomic layer deposition chamber

22. The method of claim 21, at least some of the at least one precursor being deposited on a surface of the substrate to form a layer.

23. The method of claim 22, further comprising:
removing undeposited precursor of the at least one precursor from the atomic layer deposition chamber.

24. The method of claim 23, removing the undeposited precursor comprising:
purging the atomic layer deposition chamber with a purge gas.

25. The method of claim 24, purging the atomic layer deposition chamber with the purge gas comprising:
purging the atomic layer deposition chamber with a purge gas while not maintaining the vacuum level that does not exceed approximately 1.0e⁻⁰⁸ torr-liters/second within the atomic layer deposition chamber.

26. The method of claim 23, further comprising, after removing the undeposited precursor:
injecting at least one second precursor into the atomic layer deposition chamber to deposit a second layer over the layer.

27. The method of claim 26, injecting the at least one second precursor comprising:
injecting the at least one second precursor while maintaining the vacuum level that does not exceed approximately 1.0e⁻⁰⁸ torr-liters/second within the atomic layer deposition chamber.

28. The method of claim 22, the layer comprising a high-k metal dielectric material.

29. The method of claim 21, further comprising, while injecting the at least one precursor into the atomic layer deposition chamber:
detecting the vacuum level within the atomic layer deposition chamber; and
adjusting a vacuum power of a vacuum to maintain the vacuum level that does not exceed approximately 1.0e⁻⁰⁸ torr-liters/second within the atomic layer deposition chamber.

30. A method, comprising:
injecting at least one precursor into an atomic layer deposition chamber in which a substrate is located while maintaining an O₂ contamination rate of less than 2.4% per minute within the atomic layer deposition chamber; and
forming a layer on a substrate positioned within the atomic layer deposition chamber by depositing at least some of the at least one precursor on a surface of the substrate.

31. The method of claim 30, further comprising:
maintaining a vacuum level that does not exceed approximately 1.0e⁻⁰⁸ torr-liters/second within the atomic layer deposition chamber to maintain the O₂ contamination rate at less than 2.4% per minute.

32. The method of claim 30, the layer comprising a high-k metal dielectric material.
